(19) United States
(12) Patent Application Publication
(10) Pub. No.: US 2026/0221184 A1
(43) Pub. Date: Jul. 30, 2026

(54) SEMICONDUCTOR DEVICE

(71) Applicant: Renesas Electronics Corporation, Tokyo (JP)

(72) Inventors: Yohei SAWADA, Tokyo (JP); Masao MORIMOTO, Tokyo (JP); Daiki KITAGATA, Tokyo (JP)

(21) Appl. No.: 19/262,258

(22) Filed: Jul. 8, 2025

Related U.S. Application Data
(60) Provisional application No. 63/790,523, filed on Apr. 17, 2025.

(30) Foreign Application Priority Data
Jan. 29, 2025 (JP) 2025-013371

(51) Int. Cl. G11C 11/418

(52) U.S. Cl. CPC G11C 11/418

(57) ABSTRACT

A semiconductor device includes a plurality of precharge circuits in addition to a plurality of read bit lines through which read data is transferred from a plurality of latch cells in a latch cell array. Each of the plurality of latch cells is composed of 10 or 12 MOS transistors including a first CMOS switch that transfers write data and a second CMOS switch that transfers read data. The plurality of precharge circuits precharges the plurality of read bit lines to an intermediate voltage between a high potential side power supply voltage and a low potential side power supply voltage before the second CMOS switches are controlled to turn on.

### CROSS-REFERENCE TO RELATED APPLICATIONS

The disclosure of Japanese Patent Application No. 63/689,217 filed on Aug. 30, 2024 including the specification, drawings and abstract is incorporated herein by reference in its entirety.

### BACKGROUND

The present invention relates to a semiconductor device, for example, a semiconductor device having a memory.

There are disclosed techniques listed below.

[Non-Patent Document 1] M. Sinangil, et al. ,“A 290 mV Ultra-Low Voltage One-Port SRAM Compiler Design Using a 12T Write Contention and Read Upset Free Bit-Cell in 7 nm FinFET Technology”, VLSI 2018.

[Non-Patent Document 2] H. Fujiwara, et al., “A 5 nm 5.7 GHz@1.0V and 1.3 GHz@0.5V 4 kb Standard-Cell-Based Two-Port Register File with a 16T Bitcell with_No Half-Selection Issue”, ISSCC 2021.

Non-Patent Document 1 discloses an SRAM macro having a memory cell formed from twelve transistors. The memory cell is composed of a write port circuit, a latch circuit, and a read port circuit. The write port circuit is composed of a transfer gate formed from two transistors. The latch circuit is composed of six transistors, including two cross-coupled CMOS inverter circuits. The read port circuit is composed of a driver circuit formed from four transistors.

Non-Patent Document 2 discloses an SRAM macro having a memory cell formed from 16 transistors. The memory cell is composed of a write port circuit, a latch circuit, and a read port circuit. The write port circuit is composed of a driver circuit formed from four transistors. The latch circuit includes two cross-coupled CMOS inverter circuits and is composed of eight transistors, supporting a bit-write mask operation as well. The read port circuit is composed of a driver circuit formed from four transistors.

### SUMMARY

In recent years, semiconductor devices that handle various types of Artificial Intelligence (AI) processing, such as image recognition, have seen widespread adoption. In such semiconductor devices, it is often desirable to temporarily store processing data at various distributed locations within the device. For this reason, a high-speed memory with a relatively small capacity is required. As such memory, flip-flops and Static Random Access Memory (SRAM) are known.

In the case of single-port SRAM, for example, a memory cell can be configured with six transistors. However, SRAM requires peripheral circuits that include various circuits, such as decoders, sense amplifiers, write assist circuits, and read assist circuits. As a result, in SRAM, the area per bit increases as the capacity decreases. That is, the area efficiency decreases. On the other hand, a flip-flop only needs to include a decoder as a peripheral circuit. However, a flip-flop is composed of, for example, two D latches, each of which is formed of about 20 transistors. Therefore, flip-flops have a large area per bit and are practically adopted only when the capacity thereof is sufficiently small.

Therefore, there is a demand for memory that complements SRAM and flip-flops in order to achieve high-speed operation and improve area efficiency. As a specific example, memory is required that is suitable for storing 128-bit data in about 16 to 64 units. One such memory is the D-latch macro. For example, a D-latch macro may be composed with latch cells, that is, memory cells formed from 16 transistors as disclosed in Non-Patent Document 2.

However, for example, assuming a case where a large number of small-capacity D-latch macros are arranged within a semiconductor device, further area reduction of each D-latch macro is desirable. On the other hand, area reduction of a D-latch macro may make it difficult to achieve high-speed operation. For example, in order to achieve high-speed operation, it is conceivable to use a latch cell including a driver circuit, as illustrated in Non-Patent Document 2. Alternatively, it is conceivable to provide a sense amplifier similar to that in the case of SRAM for a read bit line connected to the latch cell. These methods are a major hindrance to area reduction. Therefore, there is a demand for technique that can appropriately achieve both area reduction and high-speed operation.

An embodiment described below has been made in consideration of the above, and other objects and novel features will become apparent from the description of the present specification and the accompanying drawings.

A semiconductor device according to one embodiment includes a pair of write selection lines that are activated during a write operation, a pair of read selection lines that are activated during a read operation, and a plurality of latch cells connected thereto. The semiconductor device also includes a plurality of read bit lines through which read data is transferred from the plurality of latch cells, and a plurality of write bit lines through which write data is transferred to the plurality of latch cells. The semiconductor device further includes a plurality of precharge circuits connected to the plurality of read bit lines. Each of the plurality of latch cells includes first and second storage nodes, first, second, third, fourth and fifth nMOS transistors, and first, second, third, fourth and fifth pMOS transistors. The first and second storage nodes store complementary data. The first nMOS transistor connected between the first storage node and a first intermediate node, the gate thereof being connected to the second storage node. The second nMOS transistor connected between the second storage node and a low potential side power supply node, the gate thereof being connected to the first storage node. The third nMOS transistor connected between the first intermediate node and the low potential side power supply node and controlled by the pair of write selection lines. The first, second, and third pMOS transistors are provided in the same manner as the first, second, and third nMOS transistors, with respect to the high potential side power supply node. The fourth nMOS transistor and the fourth pMOS transistor configure a first CMOS switch controlled by the pair of write selection lines, and, when controlled to turn on, connect a predetermined write bit line to the first storage node. The fifth nMOS transistor and the fifth pMOS transistor configure a second CMOS switch controlled by the pair of read selection lines, and, when controlled to turn on, connect a predetermined read bit line to the second storage node. The plurality of precharge circuits precharges the plurality of read bit lines to an intermediate voltage between a high potential side power supply voltage and a low potential side power supply voltage before the second CMOS switches are controlled to turn on.

According to the embodiment, in a semiconductor device having a small-capacity memory, it is possible to appropriately achieve both area reduction and high-speed operation.

### BRIEF DESCRIPTION OF THE DRAWINGS

FIG. 1 is a schematic diagram illustrating a configuration example of a semiconductor device according to an embodiment.

FIG. 2 is a schematic diagram illustrating a configuration example of a main part of a peripheral circuit in a memory illustrated in FIG. 1.

FIG. 3 is a circuit diagram illustrating a configuration example of a latch cell in FIG. 1.

FIG. 4 is a schematic diagram illustrating an operation example of a precharge circuit in FIG. 2.

FIG. 5A is a timing chart illustrating an example of a write operation by the latch cell illustrated in FIG. 3.

FIG. 5B is a schematic diagram for supplementarily explaining the operation illustrated in FIG. 5A.

FIG. 6A is a timing chart illustrating an example of the read operation by the latch cell illustrated in FIG. 3.

FIG. 6B is a schematic diagram for supplementarily explaining the operation illustrated in FIG. 6A.

FIG. 7A is a timing chart illustrating an example of a bit-write mask operation by the latch cell illustrated in FIG. 3.

FIG. 7B is a schematic diagram for supplementarily explaining the operation illustrated in FIG. 7A.

FIG. 8 is a circuit diagram illustrating a more detailed configuration example of a data input/output circuit.

FIG. 9 is a schematic diagram illustrating an operation example of precharge circuits in FIG. 8.

FIG. 10 is a circuit diagram illustrating a configuration example of a latch cell serving as a comparative example.

### DETAILED DESCRIPTION

In the following embodiment, the description will be divided into a plurality of sections for convenience, where necessary. However, unless explicitly stated otherwise, these are not mutually independent, but one is, in whole or in part, modifications, details, supplementary explanations or the like of another. Further, when referring to the number of elements (including quantity, numerical values, amounts, ranges, etc.), unless explicitly stated or inherently limited by principle to a specific number, such references should not be construed as limiting to that specific number. That is, the number of elements may be greater or smaller than the specific number.

Furthermore, in the embodiment, constituent elements (including procedural steps) are not necessarily essential, unless explicitly stated or clearly essential based on underlying principles. Similarly, when referring to the shapes, positional relationships, or the like of constituent elements, unless explicitly stated or clearly inapplicable based on underlying principles, such references are intended to include those that are substantially similar or approximate. The same applies to the numerical values and ranges mentioned above.

In the embodiment, a Metal-Oxide-Semiconductor Field Effect Transistor (MOSFET) is referred to as a MOS transistor. A p-channel MOSFET and an n-channel MOSFET are referred to as a pMOS transistor and an nMOS transistor, respectively. In the embodiment, for the sake of simplicity in explanation, a MOS transistor using an oxide film as a gate insulating film is used for description. However, the gate insulating film is not necessarily limited to an oxide film.

Hereinafter, an embodiment of the present invention will be described in detail with reference to the drawings. In all the drawings for explaining the embodiment, the same reference numerals are basically assigned to the same components, and repeated explanations thereof are omitted.

### Overview of Semiconductor Device

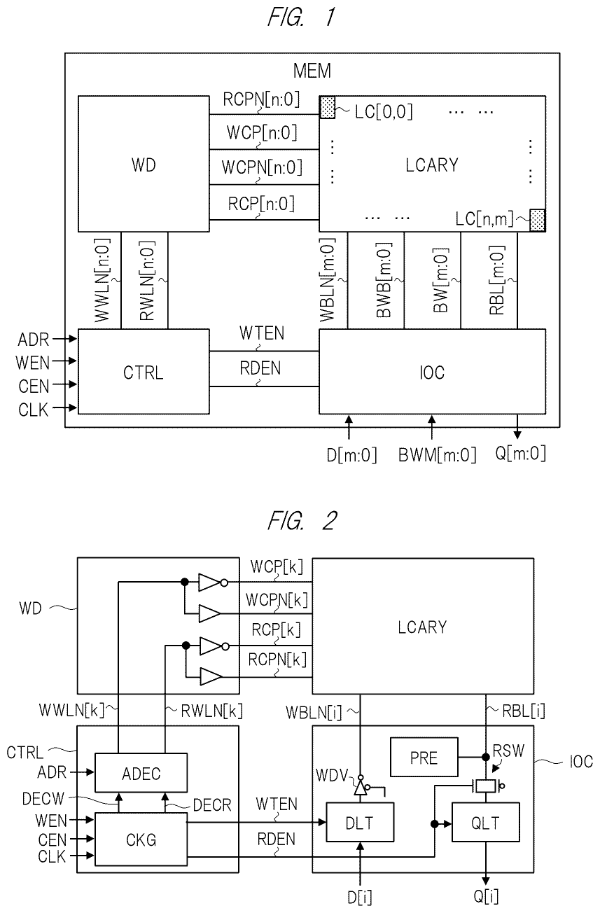

FIG. 1 is a schematic diagram illustrating a configuration example of a semiconductor device according to an embodiment. FIG. 2 is a schematic diagram illustrating a configuration example of a main part of a peripheral circuit in a memory MEM illustrated in FIG. 1. The semiconductor device according to the embodiment includes at least the memory MEM as illustrated in FIG. 1. The memory MEM is, for example, a D-latch macro configured from a hard macro. The semiconductor device includes, for example, various logic circuits that handle various AI processing. In this case, the semiconductor device may include the memories MEM as illustrated in FIG. 1 distributed at various locations within the device in order to temporarily store processing data from the various logic circuits.

The memory MEM illustrated in FIG. 1 includes a latch cell array LCARY, a memory control circuit CTRL, a word driver circuit WD, and a data input/output circuit IOC. The memory control circuit CTRL, the word driver circuit WD, and the data input/output circuit IOC are peripheral circuits of the latch cell array LCARY. The latch cell array LCARY includes N(=n+1)×M(=m+1) latch cells LC[0,0] to LC[n, m] arranged in a matrix configuration. In the specification, a plurality of latch cells LC[0,0] to LC[n, m] is collectively referred to as “latch cell LC”.

The memory control circuit CTRL controls the entire memory MEM. As illustrated in FIG. 2, the memory control circuit CTRL mainly includes a clock generation circuit CKG and an address decoder ADEC. The clock generation circuit CKG receive, from outside of the memory MEM, for example, a clock signal CLK, a chip enable signal CEN, a write enable signal WEN, and the like. The clock generation circuit CKG outputs a write decode command signal DECW or a read decode command signal DECR to the address decoder ADEC based on the input signal. Also, the clock generation circuit CKG outputs a write enable signal WTEN or a read enable signal RDEN to the data input/output circuit IOC.

The address decoder ADEC receives an address signal ADR from outside the memory MEM. The address decoder ADEC activates one write word line WWLN[k] based on the address signal ADR in accordance with the write decode command signal DECW. The write word line WWLN[k] is any one of the N write word lines WWLN[n:0] illustrated in FIG. 1. Similarly, the address decoder ADEC activates one read word line RWLN[k] based on the address signal ADR in accordance with the read decode command signal DECR. The read word line RWLN[k] is any one of the N read word lines RWLN[n:0] illustrated in FIG. 1.

As illustrated in FIG. 1, the word driver circuit WD drives a pair of complementary signal lines, specifically N pairs of read selection lines RCP[n:0] and RCPN[n:0]. The N read selection lines RCP[n:0] are non-inverted signal lines. In the specification, the N read selection lines RCP[n:0] are collectively referred to as non-inverted read selection lines RCP, or simply as read selection lines RCP. On the other hand, the remaining N read selection lines RCPN[n:0] are inverted signal lines. In the specification, the N read selection lines RCPN[n:0] are collectively referred to as inverted read selection lines RCPN, or simply as read selection lines RCPN.

Further, the word driver circuit WD drives a pair of complementary signal lines, specifically N pairs of write selection lines WCP[n:0] and WCPN[n:0]. The N write selection lines WCP[n:0] are non-inverted signal lines. In the specification, the N write selection lines WCP[n:0] are collectively referred to as non-inverted write selection lines WCP, or simply as write selection lines WCP. On the other hand, the remaining N write selection lines WCPN[n:0] are inverted signal lines. In the specification, the N write selection lines WCPN[n:0] are collectively referred to as inverted write selection lines WCPN, or simply as write selection lines WCPN.

As illustrated in FIG. 2, the word driver circuit WD receives the signal of each read word line RWLN[k] and drives each inverted read selection line RCPN[k]. Also, the word driver circuit WD inverts the signal of each read word line RWLN[k] to drive each non-inverted read selection line RCP[k]. Similarly, the word driver circuit WD receives the signal of each write word line WWLN[k] and drives each inverted write selection line WCPN[k]. Further, the word driver circuit WD inverts the signal of each write word line WWLN[k] to drive each non-inverted write selection line WCP[k].

The data input/output circuit IOC controls the input/output of data between the memory MEM and the outside. Specifically, the data input/output circuit IOC mainly includes a write latch circuit DLT and a write driver WDV as a write circuit. Further, the data input/output circuit IOC mainly includes a read switch RSW and a read latch circuit QLT as a read circuit. Furthermore, the data input/output circuit IOC includes precharge circuits PRE as read circuits, the details of which will be described later.

First, in write operation, the data input/output circuit IOC receives M-bit input data D[m:0] from outside the memory MEM, as illustrated in FIG. 1. The write latch circuit DLT latches the M-bit input data D[m:0] as write data in accordance with the write enable signal WTEN. The write driver WDV transfers the latched M-bit write data to the latch cell array LCARY via M inverted write bit lines WBLN[m:0].

The M-bit write data transferred from the write driver WDV is written into M latch cells LC connected to the activated write selection lines WCP. In the specification, the M inverted write bit lines WBLN[m:0] are collectively referred to as the inverted write bit lines WBLN, or simply as the write bit lines WBLN.

On the other hand, in read operation, the data input/output circuit IOC receives read data from the M latch cells LC via the M non-inverted read bit lines RBL[m:0]. The M latch cells LC are cells connected to activated read selection lines RCP. In this specification, the M non-inverted read bit lines RBL[m:0] are collectively referred to as non-inverted read bit lines RBL, or simply as read bit lines RBL.

The read latch circuit QLT receives and latches read data from the M latch cells LC via a read switch RSW, in response to the read enable signal RDEN. That is, unlike conventional SRAM, the read latch circuit QLT receives and latches the read data without passing through a sense amplifier. Then, the read latch circuit QLT outputs the latched M-bit read data to the outside as M-bit output data Q[m:0].

As illustrated in FIG. 1, the data input/output circuit IOC further receives an M-bit bit-write mask signal BWM[m:0] from outside the memory MEM. The bit-write mask signal BWM[m:0] is used to mask some bits of the M-bit input data D[m:0] during the write operation. As a result, for example, a read-modify-write operation can be eliminated.

During a bit-write mask operation, the write driver WDV illustrated in FIG. 2 outputs a high impedance on the write bit lines WBLN[k] for the bits to be masked. As a result, the latch cell LC connected to the write bit lines WBLN[k] can retain the currently stored data regardless of the write operation.

In addition, during the bit-write mask operation, the data input/output circuit IOC drives a pair of complementary signal lines, specifically, M pairs of bit-write mask selection lines BW[m:0] and BWB[m:0]. Details will be described later, but the driving of the selection lines allows the latch cell LC to retain the currently stored data. In this specification, the M inverted bit-write mask selection lines BWB[m:0] are collectively referred to as the inverted bit-write mask selection lines BWB, or simply the bit-write mask selection lines BWB. In this specification, the M non-inverted bit-write mask selection lines BW[m:0] are collectively referred to as the non-inverted bit-write mask selection lines BW, or simply the bit-write mask selection lines BW.

Here, in FIG. 1, the value of M (=m+1), which represents the bit width, is, for example, 128, 256, 512, or 1024. In addition, the value of N (=n+1), which represents the number of word lines, is, for example, 16, 32, or 64. Generally, in this range of memory capacity, a D-latch macro can be advantageous over flip-flops and SRAM in terms of area efficiency. The D-latch macro can be considered a macro whose area ratio between the data storage area and the peripheral circuit area is intermediate between a flip-flop and SRAM.

For example, SRAM may include a number of sense amplifiers and various assist circuits, depending on the bit width, within the data input/output circuit IOC. Therefore, as the bit width increases, the area ratio of the data input/output circuit IOC becomes higher. On the other hand, in a D-latch macro, such sense amplifiers and various assist circuits are not required. Therefore, the area ratio of the data input/output circuit IOC does not increase significantly even as the bit width increases. As a result, in a D-latch macro, high area efficiency can be maintained even when the bit width increases.

It should be noted that FIG. 1 illustrates an example in which the memory MEM is a single-port memory. However, the memory MEM may be a dual-port memory capable of performing the read and write operations independently. In this case, the memory MEM receives an address signal for reading and an address signal for writing from the outside. Accordingly, the read selection lines RCP and the write selection lines WCP can be activated simultaneously.

### Configuration of Latch Cell (Embodiment)

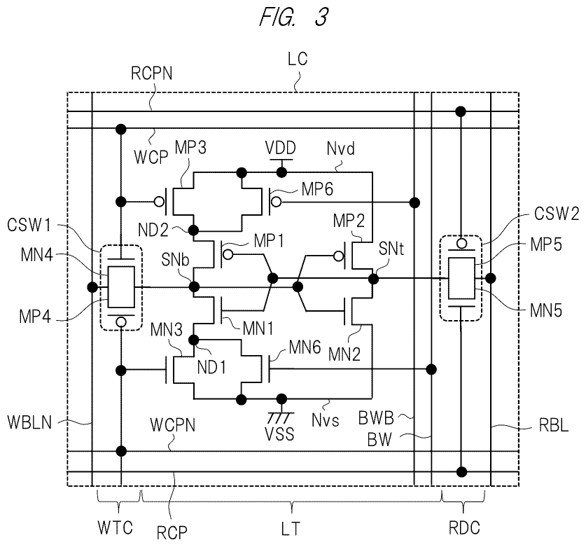

FIG. 3 is a circuit diagram illustrating a configuration example of a latch cell in FIG. 1. The latch cell LC illustrated in FIG. 3 includes a write port circuit WTC, a latch circuit LT, and a read port circuit RDC. The latch cell LC also includes an inverted storage node (first storage node) SNb and a non-inverted storage node (second storage node) SNt that store complementary data.

The latch circuit LT includes four nMOS transistors MN1 to MN3 and MN6, and four pMOS transistors MP1 to MP3 and MP6. The pMOS transistor (first pMOS transistor) MP1 and the nMOS transistor (first nMOS transistor) MN1 configure a first inverter circuit. The first inverter circuit performs an inversion operation on a signal, using the non-inverted storage node SNt and the inverted storage node SNb as an input and an output, respectively.

The pMOS transistor (second pMOS transistor) MP2 and the nMOS transistor (second nMOS transistor) MN2 configure a second inverter circuit. The second inverter circuit performs an inversion operation on a signal, using the inverted storage node SNb and the non-inverted storage node SNt as an input and an output, respectively.

The pMOS transistor (third pMOS transistor) MP3 is connected between the first inverter circuit and a high potential side power supply node Nvd. The nMOS transistor (third nMOS transistor) MN3 is connected between the first inverter circuit and a low potential side power supply node Nvs. A high potential side power supply voltage VDD is supplied to the high potential side power supply node Nvd. A low potential side power supply voltage VSS is supplied to the low potential side power supply node Nvs.

Also, the pMOS transistor (sixth pMOS transistor) MP6 is connected in parallel with the pMOS transistor MP3. The nMOS transistor (sixth nMOS transistor) MN6 is connected in parallel with the nMOS transistor MN3. Although the details will be described later, the pMOS transistor MP6 and the nMOS transistor MN6 are provided to implement a bit-write mask function. Therefore, the pMOS transistor MP6 and the nMOS transistor MN6 may be omitted when the bit-write mask function is not required.

The pMOS transistor (fourth pMOS transistor) MP4 and the nMOS transistor (fourth nMOS transistor) MN4 configure the write port circuit. The pMOS transistor MP4 and the nMOS transistor MN4 configure a Complementary MOS (CMOS) switch (first CMOS switch) CSW1, in other words, a transfer gate. When controlled to turn on, the CMOS switch CSW1 transfers write data to the inverted storage node SNb.

Meanwhile, the pMOS transistor (fifth pMOS transistor) MP5 and the nMOS transistor (fifth nMOS transistor) MN5 configure the read port circuit. The pMOS transistor MP4 and the nMOS transistor MN4 configure a CMOS switch (second CMOS switch) CSW2, in other words, a transfer gate. When controlled to turn on, the CMOS switch CSW2 transfers read data to the non-inverted storage node SNt.

Here, more specifically, the latch cell LC illustrated in FIG. 3 is connected to eight signal lines (WCP, WCPN, RCP, RCPN, BW, BWB, WBLN, and RBL) as described in FIGS. 1 and 2. A pair of write selection lines WCP and WCPN are activated during the write operation. A pair of read selection lines RCP and RCPN are activated during the read operation. The read bit line RBL transfers read data from the latch cell LC. The write bit line WBLN transfers write data to the latch cell LC.

A pair of bit-write mask selection lines BW and BWB are activated when the bit-write mask operation is performed. That is, the pair of bit-write mask selection lines BW and BWB are activated when a high impedance write operation is performed on any one of the plurality of latch cells LC. In other words, these signal lines are activated to retain the data stored in any of the plurality of latch cells regardless of the write operation.

The nMOS transistor (first nMOS transistor) MN1 is connected between the inverted storage node SNb and an intermediate node (first intermediate node) ND1. The gate of the nMOS transistor MN1 is connected to the non-inverted storage node SNt. The nMOS transistor (second nMOS transistor) MN2 is connected between the non-inverted storage node SNt and the low potential side power supply node Nvs. The gate of the nMOS transistor MN2 is connected to the inverted storage node SNb. The nMOS transistor (third nMOS transistor) MN3 is connected between the intermediate node ND1 and the low potential side power supply node Nvs. The gate of the nMOS transistor MN3 is connected to the inverted write selection line WCPN.

The pMOS transistor (first pMOS transistor) MP1 is connected between the inverted storage node SNb and an intermediate node (second intermediate node) ND2. The gate of the pMOS transistor MP1 is connected to the non-inverted storage node SNt. The pMOS transistor (second pMOS transistor) MP2 is connected between the non-inverted storage node SNt and the high potential side power supply node Nvd. The gate of the pMOS transistor MP2 is connected to the inverted storage node SNb. The pMOS transistor (third pMOS transistor) MP3 is connected between the intermediate node ND2 and the high potential side power supply node Nvd. The gate of the pMOS transistor MP3 is connected to the non-inverted write selection line WCP.

The nMOS transistor (fourth nMOS transistor) MN4 and the pMOS transistor (fourth pMOS transistor) MP4 is connected in parallel between the write bit line WBLN and the inverted storage node SNb. The gate of the nMOS transistor MN4 is connected to the non-inverted write selection line WCP. The gate of the pMOS transistor MP4 is connected to the inverted write selection line WCPN. Thus, the CMOS switch CSW1 is controlled by the pair of write selection lines WCP and WCPN.

The nMOS transistor (fifth nMOS transistor) MN5 and the pMOS transistor (fifth pMOS transistor) MP5 is connected in parallel between the read bit line RBL and the non-inverted storage node SNt. The gate of the nMOS transistor MN5 is connected to the non-inverted read selection line RCP. The gate of the pMOS transistor MP5 is connected to the inverted read selection line RCPN. Thus, the CMOS switch CSW2 is controlled by the pair of read selection lines RCP and RCPN.

The nMOS transistor (sixth nMOS transistor) MN6 is connected between the intermediate node ND1 and the low potential side power supply node Nvs. The gate of the nMOS transistor MN6 is connected to the non-inverted bit-write mask selection line BW. The pMOS transistor (sixth pMOS transistor) MP6 is connected between the intermediate node ND2 and the high potential side power supply node Nvd. The gate of the pMOS transistor MP6 is connected to the inverted bit-write mask selection line BWB. Thus, the nMOS transistor MN6 and the pMOS transistor MP6 are controlled by the pair of bit-write mask selection lines BW and BWB.

### Memory as Comparative Example

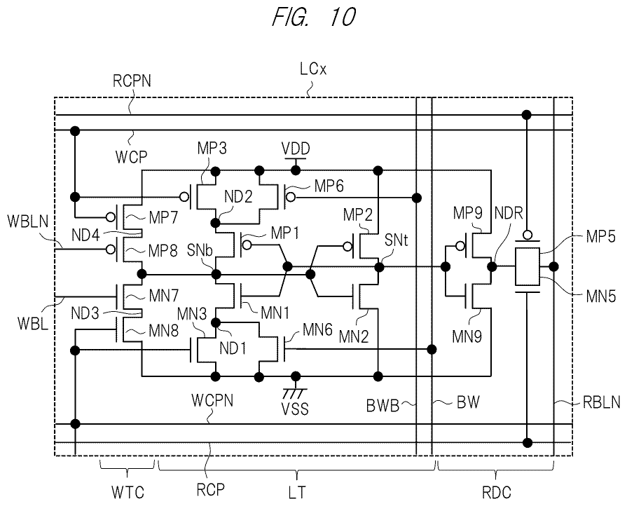

FIG. 10 is a circuit diagram illustrating a configuration example of a latch cell LCx serving as a comparative example. The latch cell LCx serving as the comparative example differs from the configuration example illustrated in FIG. 3 in configurations of the write port circuit WTC and the read port circuit RDC. The write port circuit WTC illustrated in FIG. 10 is composed of a driver circuit including two pMOS transistors MP7 and MP8 and two nMOS transistors MN7 and MN8. The read port circuit RDC is composed of a driver circuit including a pMOS transistor MP9 and an nMOS transistor MN9, and a transfer gate. The transfer gate is composed of a pMOS transistor MP5 and an nMOS transistor MN5, as in the case of FIG. 3.

Accordingly, the latch cell LCx serving as the comparative example is composed of a total of 16 transistors. On the other hand, the latch cell LC illustrated in FIG. 3 is composed of a total of 12 transistors, or a total of 10 transistors when the bit-write mask function is not required. As a result, area reduction can be achieved in a semiconductor device having a small-capacity memory. More specifically, the use of a D-latch macro itself enables area reduction of the semiconductor device. In addition, by reducing the number of transistors in the latch cell LC, area reduction of the D-latch macro itself can be achieved, leading to further area reduction of the semiconductor device. In particular, even in cases where D-latch macros are distributed throughout various parts of the semiconductor device, an increase in area can be suppressed.

However, as illustrated in FIG. 3, if the read port circuit RDC is composed of only transfer gates, there is a concern that it may be difficult to increase the memory speed, specifically, to reduce the read access time. Specifically, the read bit line RBL illustrated in FIG. 3 is driven to either a high “H” level or a low “L” level in accordance with the read data. Then, the read bit line RBL holds the “H” level or “L” level by means of parasitic capacitance during the period until the next read operation is performed.

Accordingly, the latch cell LC illustrated in FIG. 3 may, during the read operation, drive the read bit line RBL, which is holding the high “H” level, to the low “L” level. At this time, the “L” level must be sufficiently close to the low potential side power supply voltage VSS in order to determine input data to the read latch circuit QLT illustrated in FIG. 2. Similarly, the latch cell LC may drive the read bit line RBL, which is holding the “L” level, to the “H” level. In this case, the “H” level must be sufficiently close to the high potential side power supply voltage VDD.

The latch cell LC illustrated in FIG. 3 does not have a driver circuit (MP9, MN9) in the read port circuit RDC, unlike the case of FIG. 3. Therefore, it may take time for the read bit line RBL to transition from the “H” level to the “L” level or from the “L” level to the “H” level. As a result, the read access time becomes longer, which may make it difficult to achieve high-speed operation of the memory MEM.

On the other hand, in order to achieve high-speed operation of the memory MEM, for example, in the data input/output circuit IOC illustrated in FIG. 2, providing a sense amplifier similar to that in the case of SRAM at a stage preceding the read latch circuit QLT is conceivable. In this case, the sense amplifier can be activated at a stage where the voltage of the read bit line RBL has approached to a certain extent either the high potential side power supply voltage VDD or the low potential side power supply voltage VSS. Subsequently, after the activation of the sense amplifier, the read latch circuit QLT can latch the data with almost no delay. However, a sense amplifier typically requires a large circuit area. As a result, area reduction of the memory may become difficult to achieve. For this reason, the precharge circuits PRE illustrated in FIG. 2 is provided.

### Overview of Precharge Circuit

The precharge circuits PRE illustrated in FIG. 2 are connected to the M read bit lines RBL[m:0] illustrated in FIG. 1. Each precharge circuit PRE precharges the read bit line RBL to an intermediate voltage VM before the CMOS switch CSW2 illustrated in FIG. 3 is controlled to turn on. Specifically, each precharge circuit PRE holds the read bit line RBL at the intermediate voltage VM, for example, while the CMOS switch CSW2 is off. The intermediate voltage VM is a voltage having an intermediate value between the high potential side power supply voltage VDD and the low potential side power supply voltage VSS, and for example, when VSS=0 V, VM is VDD/2.

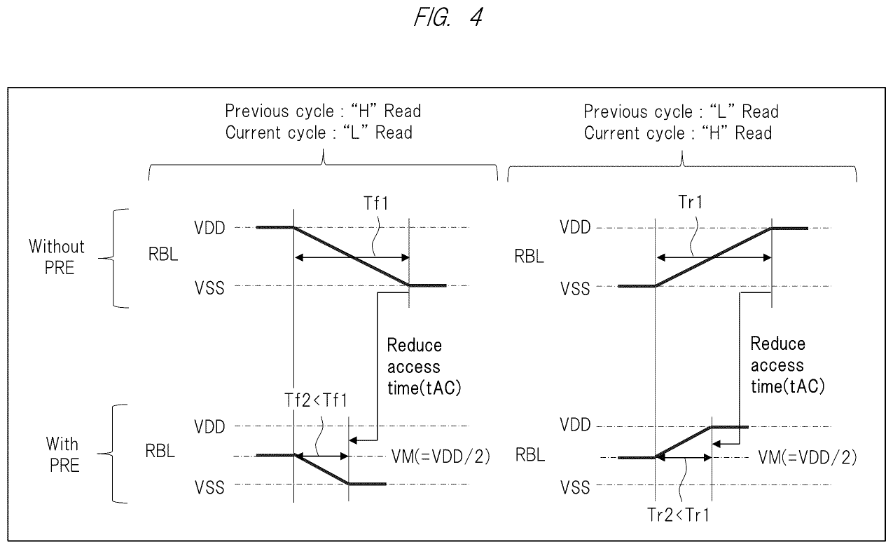

FIG. 4 is a schematic diagram illustrating an operation example of each precharge circuit in FIG. 2. Here, for comparison, an operation example of a case where the precharge circuit PRE is not provided is also illustrated. In FIG. 4, in the case where the precharge circuit PRE is not provided, the latch cell LC needs to drive the read bit line RBL, which is holding the VDD level, to the VSS level. Or, the latch cell LC needs to drive the read bit line RBL, which is holding the VSS level, to the VDD level. As a result, a read transition time Tf1 to the “L” level and the read transition time Tr1 to the “H” level of the read bit line RBL could become longer.

On the other hand, in the case where the precharge circuit PRE is provided, the latch cell LC only needs to drive the read bit line RBL, which is holding an intermediate voltage VM, here, a voltage level “VM=VDD/2”, to the VSS level. Or, the latch cell LC only needs to drive the read bit line RBL, which is holding the VM level, to the VDD level. As a result, a read transition time Tf2 to the “L” level and the read transition time Tr2 to the “H” level of the read bit line RBL can be reduced. Ideally, in the case where the precharge circuit PRE is provided, the read transition time can be reduced to half as compared with the case where the precharge circuit PRE is not provided.

This allows the read access time to be reduced, and high-speed operation of the memory MEM to be implemented. Furthermore, although a detailed configuration example will be described later, the precharge circuit PRE can be implemented in a smaller area than the sense amplifier. Accordingly, this also makes it possible to suppress the area overhead associated with high-speed operation of the memory MEM. That is, by using the memory MEM according to one embodiment, it is possible to appropriately achieve both area reduction and high-speed operation. Note that the intermediate voltage VM is not necessarily limited to “VM=VDD/2”; it may be any value lower than the high potential side power supply voltage VDD and higher than the low potential side power supply voltage VSS. For example, when a difference occurs between the rising transition time and the falling transition time of a signal, an offset may be added to the intermediate voltage VM in a direction that compensates for this difference.

### Operation of Latch Cell

### [Write Operation]

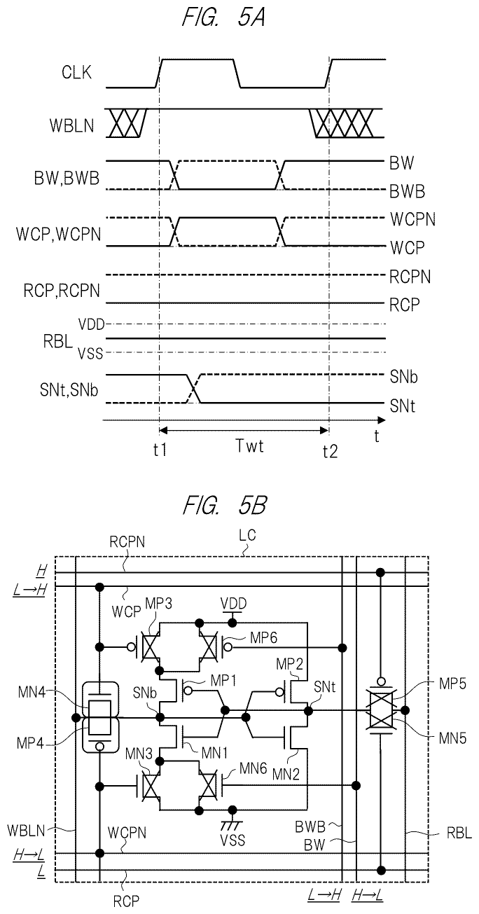

FIG. 5A is a timing chart illustrating an example of a write operation by the latch cell LC illustrated in FIG. 3. FIG. 5B is a schematic diagram for supplementarily explaining the operation illustrated in FIG. 5A. FIG. 5B illustrates a states of each signal line and an on/off state of each transistor in the latch cell LC during the write period. In FIG. 5A, the period from time t1 to time t2, which is one cycle of a clock signal CLK, is a write period Twt.

During the write period Twt, the read selection line RCP is in an inactive state, which is at the “L” level in this case. Therefore, the pMOS transistor MP5 and the nMOS transistor MN5 are in the off state. In addition, the intermediate voltage VM is applied to the read bit line RBL by the precharge circuit PRE.

On the other hand, the write selection line WCP transitions from the inactive state to an active state, that is, from the “L” level to the “H” level in this case. Accordingly, the pMOS transistor MP4 and the nMOS transistor MN4 switch from the off state to the on state. Also, the pMOS transistor MP3 and the nMOS transistor MN3 switch from the on state to the off state. Incidentally, since the bit-write mask operation is not performed here, the bit-write mask selection line BW transitions from the active state to the inactive state, that is, from the “H” level to the “L” level in this case. Accordingly, the pMOS transistor MP6 and the nMOS transistor MN6 switch from the on state to the off state.

In this state, assume a case in which, for example, the inverted storage node SNb is rewritten from the “L” level to the “H” level. The write bit line, specifically the inverted write bit line WBLN, is at the “H” level at time t1. The pMOS transistor MP4 and the nMOS transistor MN4, which are in the on state, transfer the “H” level to the storage node SNb at the “L” level.

At this point, the write bit line WBLN is driven by the write driver WDV illustrated in FIG. 2. On the other hand, the supply of the power supply voltage VSS to the nMOS transistor MN1 is cut off. Therefore, the inverted storage node SNb can be rewritten to the “H” level. Further, by receiving the “H” level, the nMOS transistor MN2 can rewrite the non-inverted storage node SNt from the “H” level to the “L” level.

Thereafter, the write selection line WCP transitions from the active state to the inactive state. The bit-write mask selection line BW transitions from the inactive state to the active state. Accordingly, the pMOS transistor MP4 and the nMOS transistor MN4 switch from the on state to the off state. Two pMOS transistors MP3 and MP6 and two nMOS transistors MN3 and MN6 switch from the off state to the on state. This completes the write operation.

### [Read Operation]

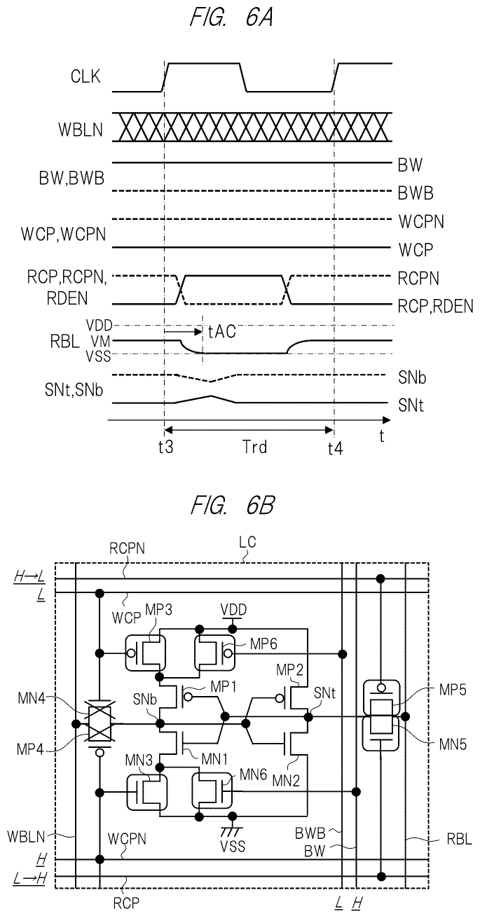

FIG. 6A is a timing chart illustrating an example of a read operation by the latch cell LC illustrated in FIG. 3. FIG. 6B is a schematic diagram for supplementarily explaining the operation illustrated in FIG. 6A. FIG. 6B illustrates a states of each signal line and an on/off state of each transistor in the latch cell LC during the read period. In FIG. 6A, the period from time t3 to time t4, which is one cycle of a clock signal CLK, is a read period Trdt.

During the read period Trd, the write selection line RCP is in an inactive state, which is at the “L” level in this case. Therefore, the pMOS transistor MP4 and the nMOS transistor MN4 are in the off state. The pMOS transistor MP3 and the nMOS transistor MN3 are in the on state. The bit-write mask selection line BW is in the active state, which is at the “H” level in this case. Therefore, the pMOS transistor MP6 and the nMOS transistor MN6 are in the on state.

On the other hand, the read selection line RCP transitions from the inactive state to the active state, that is, from the “L” level to the “H” level in this case. Therefore, the pMOS transistor MP5 and the nMOS transistor MN5 switch from the off state to the on state. The read enable signal RDEN, illustrated in FIG. 2, also transitions in the same manner as the read selection line RCP, for example. In this case, the read latch circuit QLT outputs the read data received during an “H” level period of the read enable signal RDEN. The read latch circuit QLT latches and outputs the read data at the falling edge of the read enable signal RDEN during an “L” level period of the read enable signal RDEN.

In this state, for example, a case is assumed in which the non-inverted storage node SNt storing the “L” level is read. The read bit line RBL is at the voltage level of the intermediate voltage VM at time t3. The pMOS transistor MP5 and the nMOS transistor MN5, which are in the on state, connect the non-inverted storage node SNt to the read bit line RBL having the VM level.

At this point, the voltage level of the non-inverted storage node SNt may temporarily rise slightly from the “L” level. In response to this, the voltage level of the inverted storage node SNb may also temporarily drop slightly from the “H” level. During the period when the pMOS transistor MP5 and the nMOS transistor MN5 are in the on state, the precharge circuit PRE is disconnected from the read bit line RBL.

Thereafter, the read selection line RCP transitions from the active state to the inactive state. Accordingly, the pMOS transistor MP5 and the nMOS transistor MN5 switch from the on state to the off state. This completes the read operation. After the read operation is completed, the precharge circuit PRE precharges the read bit line RBL to the intermediate voltage VM again. Here, the time from time t3 until the read bit line RBL reaches the VSS level is the read access time tAC. As illustrated in FIG. 4, by shortening the read transition time Tf2, the read access time tAC can also be shortened.

### [Bit-Write Mask Operation]

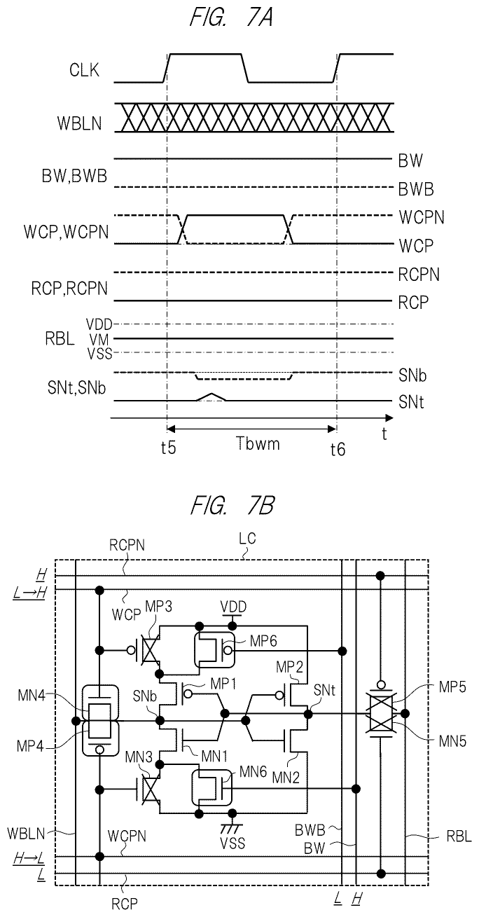

FIG. 7A is a timing chart illustrating an example of a bit-write mask operation by the latch cell LC illustrated in FIG. 3. FIG. 7B is a schematic diagram for supplementarily explaining the operation illustrated in FIG. 7A. FIG. 7B illustrates a states of each signal line and an on/off state of each transistor in the latch cell LC during a bit-write mask period. In FIG. 7A, the period from time t5 to time t6, which is one cycle of a clock signal CLK, is a bit-write mask period Tbwm.

The bit-write mask period Tbwm is different from the write period Twt illustrated in FIG. 5A in the state of the bit-write mask selection line BW. That is, during the bit-write mask period Tbwm, the bit-write mask selection line BW is in an active state, which is at the “H” level in this case. Accordingly, the pMOS transistor MP6 and the nMOS transistor MN6 are in the on state. As a result, unlike the case illustrated in FIG. 5A, the inverted storage node SNb is driven by either the high potential side power supply voltage VDD or the low potential side power supply voltage VSS.

In this state, for example, a case is assumed in which the inverted storage node SNb stores the “H” level. As described with reference to FIGS. 1 and 2, the write bit line WBLN is in a high-impedance state during the bit-write mask period Tbwm. That is, the voltage level of the write bit line WBLN is indefinite. The pMOS transistor MP4 and nMOS transistor MN4, which are in the on state, connect the write bit line WBLN having an indefinite voltage level to the inverted storage node SNb.

At this point, if the write bit line WBLN is at the “L” level, the voltage level of the inverted storage node SNb may temporarily drop slightly from the “H” level. Accordingly, the voltage level of the non-inverted storage node SNt may temporarily rise slightly from the “L” level. However, since each storage node SNb and SNt is driven by either the high potential side power supply voltage VDD or the low potential side power supply voltage VSS, the original voltage level can be maintained. As a result, the inverted storage node SNb can maintain the “H” level regardless of the write operation.

### Details of Data Input/Output Circuit

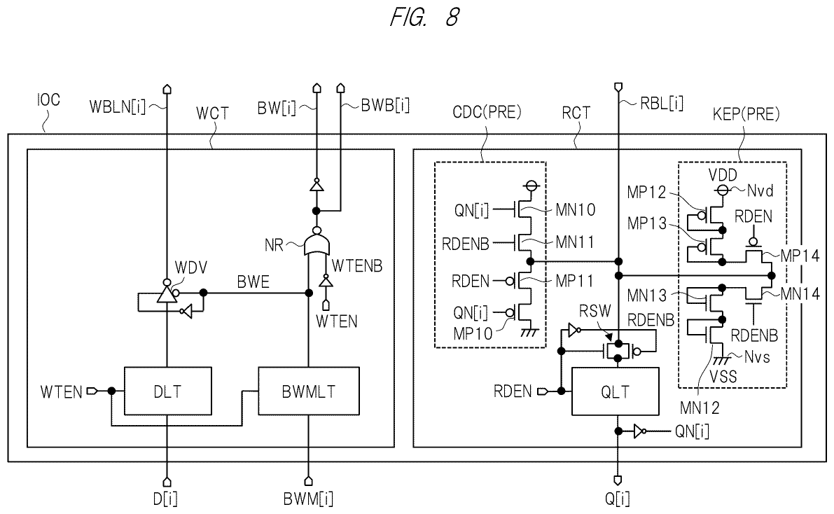

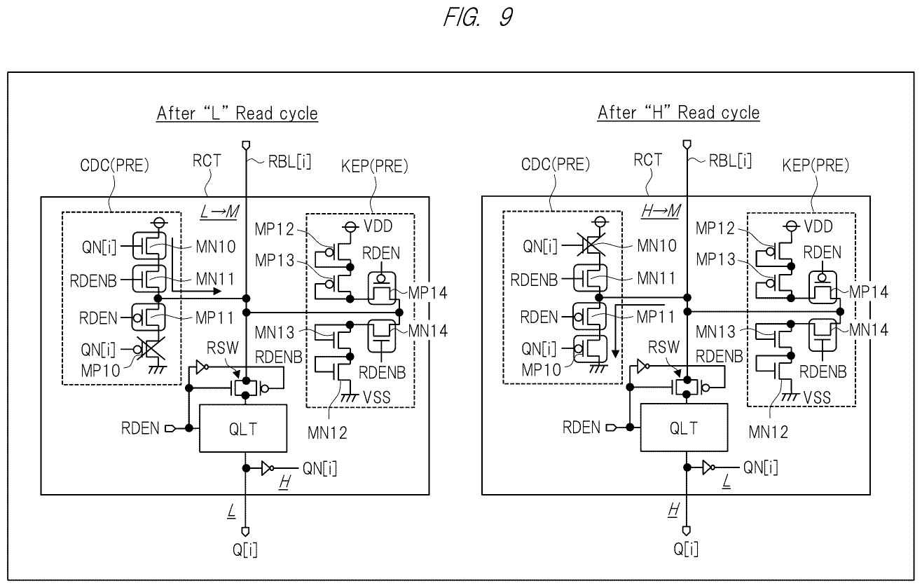

FIG. 8 is a circuit diagram illustrating a more detailed configuration example of a data input/output circuit IOC in FIG. 1. The data input/output circuit IOC illustrated in FIG. 8 includes a write circuit WCT and a read circuit RCT. The write circuit WTCT includes, in addition to the write latch circuit DLT and the write driver WDV illustrated in FIG. 2, a bit-write mask latch circuit BWMLT and a NOR gate NR. As described in FIG. 2, the write latch circuit DLT latches input data D[i] as write data in accordance with the write enable signal WTEN. The write driver WDV drives the write bit line WBLN[i] based on the latched write data.

Meanwhile, the bit-write mask latch circuit BWMLT latches an externally supplied bit-write mask signal BWM[i] in accordance with the write enable signal WTEN. Then, the bit-write mask latch circuit BWMLT outputs a bit-write mask enable signal BWE which is the latched result. For example, when the bit-write mask signal BWM[i] is at the “H” level, that is, the asserted level, the bit-write mask enable signal BWE also becomes “H” level.

Here, the write driver WDV is a tri-state circuit that is controlled by the bit-write mask enable signal BWE. The write driver WDV outputs a high impedance to the write bit line WBLN[i] when the bit-write mask enable signal BWE is at the “H” level. On the other hand, when the bit-write mask enable signal BWE is at the “L” level, the write driver WDV drives the write bit line WBLN[i] based on the write data from the write latch circuit DLT.

The NOR gate NR receives the inverted write enable signal WTENB, which is the inversion of the write enable signal WTEN, and the bit-write mask enable signal BWE, and performs a NOR operation. The NOR gate NR outputs the signal obtained by the NOR operation to the inverted bit-write mask selection line BWB[i]. Also, the NOR gate NR outputs the signal obtained by the NOR operation to the non-inverted bit-write mask selection line BW[i].

For example, when the write enable signal WTEN is at the “L” level, that is, during a non-write operation, the inverted bit-write mask selection line BWB[i] is fixed at the “L” level. On the other hand, when the write enable signal WTEN is at the “L” level, the voltage level of the inverted bit-write mask selection line BWB[i] is controlled based on the bit-write mask enable signal BWE. That is, the voltage level of the inverted bit-write mask selection line BWB[i] is controlled to the “L” level or the “H” level when the bit-write mask enable signal BWE is at the “H” level or the “L” level, respectively.

The read circuit RCT includes, as in the case of FIG. 2, a read latch circuit QLT, a read switch RSW, and a precharge circuit PRE. As described in FIG. 2, the read latch circuit QLT receives read data from the read bit line RBL[i] via the read switch RSW and latches it in accordance with the read enable signal RDEN. Then, the read latch circuit QLT outputs the latched read data to the outside as output data Q[i].

The read switch RSW is composed of, for example, a CMOS switch. The read switch RSW is controlled by the read enable signal RDEN and an inverted read enable signal RDENB, which is its inverted signal. The read switch RSW connects the read bit line RBL[i] to the read latch circuit QLT when the read enable signal RDEN is at the “H” level, that is, the asserted level.

The precharge circuit PRE includes, for example, a charge/discharge circuit CDC and a voltage holding circuit KEP. The voltage holding circuit KEP maintains the voltage of the read bit line RBL[i] at an intermediate voltage VM during the “L” level period of the read enable signal RDEN, that is, during a negated period. As illustrated in FIG. 6A, the negated period of the read enable signal RDEN also corresponds to the off period of the CMOS switch CSW2.

Specifically, the voltage holding circuit KEP includes three pMOS transistors MP12 to MP14 and three nMOS transistors MN12 to MN14. The three pMOS transistors MP12 to MP14 are connected in series between the high potential side power supply node Nvd and the read bit line RBL[i]. The three nMOS transistors MN12 to MN14 are connected in series between the low potential side power supply node Nvs and the read bit line RBL[i].

The two pMOS transistors MP12 and MP13 are configured as diode-connected pMOS transistors for voltage division. Similarly, the two nMOS transistors MN12 and MN13 are configured as diode-connected nMOS transistors for voltage division. The pMOS transistors and the nMOS transistors for voltage division serve as a voltage divider circuit that divides the high potential side power supply voltage VDD with reference to the low potential side power supply voltage VSS at a predetermined voltage dividing ratio. The voltage dividing ratio is, for example, 1 to 2.

On the other hand, the pMOS transistor MP14 and the nMOS transistor MN14 are controlled to turn on during the negated period of the read enable signal RDEN and to turn off during the asserted period. Accordingly, the pMOS transistor MP14 and the nMOS transistor MN14 serve as a precharge switch (first precharge switch). The precharge switch connects the voltage divider circuit to the read bit line RBL[i] during the negated period of the read enable signal RDEN.

Here, when the precharge switch turns on, both the diode-connected pMOS transistors MP12 and MP13 and the nMOS transistors MN12 and MN13 are connected to the read bit line RBL[i]. Consequently, the voltage holding circuit KEP by itself may have difficulty in rapidly to a certain extent bringing the voltage level from the “H” level or “L” level closer to the “M” level, which is the intermediate voltage VM, relatively rapidly. Therefore, the charge/discharge circuit CDC is provided.

It should be noted that, after the voltage level of the read bit line RBL[i] approaches the “M” level to a certain extent, the voltage holding circuit KEP can set the voltage level of the read bit line RBL[i] to the “M” level and maintain thereof. That is, the voltage holding circuit KEP can maintain the voltage level of the read bit line RBL[i] at the “M” level even if, for example, a leakage current occurs in the read bit line RBL[i].

The charge/discharge circuit CDC charges or discharges the read bit line RBL[i] during the negated period of the read enable signal RDEN, in accordance with the latch data of the read latch circuit QLT. That is, the charge/discharge circuit CDC switches between charging and discharging depending on the logic level of the output data Q[i]. This allows the charge/discharge circuit CDC to bring the voltage level of the read bit line RBL[i] closer to the “M” level relatively rapidly when the read enable signal RDEN is negated.

More specifically, the charge/discharge circuit CDC includes two nMOS transistors MN10 and MN11, and two pMOS transistors MP10 and MP11. The two nMOS transistors MN10 and MN11 are connected in series between the high potential side power supply node Nvd and the read bit line RBL[i]. The two pMOS transistors MP10 to MP11 are connected in series between the low potential side power supply node Nva and the read bit line RBL[i].

The nMOS transistor MN10 is a charging nMOS transistor that charges the read bit line RBL[i] toward a voltage equal to the high potential side power supply voltage VDD minus the threshold voltage drop. The nMOS transistor MN10 is controlled to turn on when the output data Q[i] is at the “L” level and inverted output data QN[i] is at the “H” level. On the other hand, the pMOS transistor MP10 is a discharging pMOS transistor that discharges the read bit line RBL[i] toward a voltage equal to the low potential side power supply voltage VSS plus the threshold voltage. The pMOS transistor MP10 is controlled to turn on when the output data Q[i] is at the “H” level and inverted output data QN[i] is at the “L” level.

The pMOS transistor MN11 and the pMOS transistor MP11 are controlled to turn on during the negated period of the read enable signal RDEN and to turn off during the asserted period. Accordingly, the nMOS transistor MN11 and the pMOS transistor MP11 serve as a precharge switch (second precharge switch). The precharge switch connects the charge/discharge circuit CDC, specifically, the nMOS transistor MN10 or the pMOS transistor MP10, to the read bit line RBL[i] during the negated period of the read enable signal RDEN.

FIG. 9 is a schematic diagram illustrating an operation example of the precharge circuits in FIG. 8. FIG. 9 illustrates a state after the read operation has been performed. First, if the read operation is performed that outputs “L” level output data Q[i], the read bit line RBL[i] holds the “L” level.

In this case, after the read operation is performed, the path on the side of the nMOS transistors MN10 and MN11 becomes conductive. As a result, the voltage level of the read bit line RBL[i] rises relatively rapidly from the “L” level toward the “M” level. After the voltage level of the read bit line RBL[i] approaches the “M” level to a certain extent, the voltage holding circuit KEP sets the voltage level to the “M” level. Then, the voltage holding circuit KEP holds the “M” level until the next read operation is performed.

On the other hand, if the read operation is performed that outputs “H” level output data Q[i], the read bit line RBL[i] holds the “H” level. In this case, after the read operation is performed, the path on the side of the pMOS transistors MP10 and MP11 becomes conductive. As a result, the voltage level of the read bit line RBL[i] drops relatively rapidly from the “H” level toward the “M” level. After the voltage level of the read bit line RBL[i] approaches the “M” level to a certain extent, the voltage holding circuit KEP sets the voltage level to the “M” level. Then, the voltage holding circuit KEP holds the “M” level until the next read operation is performed.

Here, the precharge circuit PRE is not required to operate as fast as the sense amplifier. In addition, the pMOS transistors MP12 and MP13 and the nMOS transistors MN12 and MN13 in the voltage holding circuit KEP illustrated in FIG. 8 operate based on mutual resistance balance. As a result of these factors, the transistor sizes of the MOS transistors that make up the precharge circuits PRE can be relatively small. Therefore, the area overhead caused by providing the precharge circuits PRE is smaller compared to providing a sense amplifier. It should be noted that the configuration of the precharge circuits PRE is not limited to that illustrated in FIG. 8, as long as a configuration can apply the intermediate voltage VM to the read bit line RBL[i] with a small area overhead.

### Main Effect of One Embodiment

As described above, in the configuration according to one embodiment, each latch cell LC that configures a D-latch macro is composed of 10 or 12 MOS transistors. Furthermore, precharge circuits PRE are provided in the D-latch macro to precharge a read bit line RBL to an intermediate voltage VM in preparation for a read operation. Consequently, in a semiconductor device having a small-capacity memory, it is possible to appropriately achieve both area reduction and high-speed operation.

In the foregoing, the invention made by the inventors of the present application has been concretely described on the basis of the embodiments. However, it is needless to say that the present invention is not limited to the foregoing embodiment, and various modifications and alterations can be made within the scope of the present invention. For example, the above-described embodiment has been described in detail to clearly explain the present invention, and is not necessarily limited to having all of the configurations described. Moreover, it is possible to replace part of the configuration of one embodiment with that of another embodiment, and it is also possible to add the configuration of another embodiment to that of one embodiment. Furthermore, with respect to parts of the configuration in each embodiment, it is possible to add to, delete from, or replace them with other configurations.

What is claimed is:

1. A semiconductor device comprising:
a pair of write selection lines, which are complementary signal lines and are activated during a write operation;
a pair of read selection lines, which are complementary signal lines and are activated during a read operation;
a plurality of latch cells connected to the pair of write selection lines and the pair of read selection lines;
a plurality of read bit lines through which read data is transferred from the plurality of latch cells;
a plurality of write bit lines through which write data is transferred to the plurality of latch cells; and
a plurality of precharge circuits connected to the plurality of read bit lines,
wherein each of the plurality of latch cells includes:
a first storage node and a second storage node that store complementary data;
a first nMOS transistor connected between the first storage node and a first intermediate node, the gate of the first nMOS transistor being connected to the second storage node;
a second nMOS transistor connected between the second storage node and a low potential side power supply node to which a low potential side power supply voltage is supplied, the gate of the second nMOS transistor being connected to the first storage node;
a third nMOS transistor connected between the first intermediate node and the low potential side power supply node and controlled by the pair of write selection lines;
a first pMOS transistor connected between the first storage node and a second intermediate node, the gate of the first pMOS transistor being connected to the second storage node;
a second pMOS transistor connected between the second storage node and a high potential side power supply node to which a high potential side power supply voltage is supplied, the gate of the second pMOS transistor being connected to the first storage node;
a third pMOS transistor connected between the second intermediate node and the high potential side power supply node and controlled by the pair of write selection lines;
a fourth nMOS transistor and a fourth pMOS transistor configuring a first CMOS switch controlled by the pair of write selection lines, the fourth nMOS transistor and the fourth pMOS transistor connecting a predetermined write bit line among the plurality of write bit lines to the first storage node when the fourth nMOS transistor and the fourth pMOS transistor are controlled to turn on; and
a fifth nMOS transistor and a fifth pMOS transistor configuring a second CMOS switch controlled by the pair of read selection lines, the fifth nMOS transistor and the fifth pMOS transistor connecting the second storage node to a predetermined read bit line among the plurality of read bit lines when the fifth nMOS transistor and the fifth pMOS transistor are controlled to turn on, and
wherein the plurality of precharge circuits precharges the plurality of read bit lines to an intermediate voltage between the high potential side power supply voltage and the low potential side power supply voltage before the second CMOS switch is controlled to turn on.

2. The semiconductor device according to claim 1,
wherein each of the plurality of precharge circuits includes:
a voltage divider circuit that divides the high potential side power supply voltage with reference to the low potential side power supply voltage; and
a first precharge switch that connects the voltage divider circuit to the predetermined read bit line during an off period of the second CMOS switch.

3. The semiconductor device according to claim 2,
wherein the voltage divider circuit includes:
a diode-connected pMOS transistor for voltage division, connected between the high potential side power supply node and the predetermined read bit line; and
a diode-connected nMOS transistor for voltage division, connected between the low potential side power supply node and the predetermined read bit line.

4. The semiconductor device according to claim 3, further comprising
a plurality of read latch circuits that latches the reads data transferred to the plurality of read bit lines,
wherein each of the plurality of precharge circuits further includes:
a charge/discharge circuit that charges or discharges the predetermined read bit line in accordance with latch data of a predetermined read latch circuit among the plurality of read latch circuits; and
a second precharge switch that connects the charge/discharge circuit to the predetermined read bit line during the off period of the second CMOS switch, and
wherein the charge/discharge circuit includes:
a charging nMOS transistor connected between the high potential side power supply node and the predetermined read bit line, and controlled to turn on when the predetermined read latch circuit latches an “L” level; and
a discharging pMOS transistor connected between the low potential side power supply node and the predetermined read bit line, and controlled to turn on when the predetermined read latch circuit latches an “H” level.

5. The semiconductor device according to claim 1, further comprising
a plurality of pairs of complementary bit-write mask selection lines which is activated when a high impedance write operation is performed on any of the plurality of latch cells, and
wherein each of the plurality of latch cells further includes:
a sixth nMOS transistor connected between the first intermediate node and the low potential side power supply node and controlled by any of a pair of bit-write mask selection lines among the plurality of pairs of bit-write mask selection lines; and
a sixth pMOS transistor connected between the second intermediate node and the high potential side power supply node and controlled by the pair of bit-write mask selection lines.

6. The semiconductor device according to claim 1, further comprising
a read latch circuit that receives and latches the read data transferred to the plurality of read bit lines without passing through a sense amplifier.
